(19) United States
(12) Patent Application Publication
(10) Pub. No.: US 2025/0254842 A1
(43) Pub. Date: Aug. 7, 2025

(54) UNDERWATER DATA CENTER

(71) Applicant: Hengliang ZHAI, Shanghai (CN)

(72) Inventor: Hengliang ZHAI, Shanghai (CN)

(21) Appl. No.: 19/186,532

(22) Filed: Apr. 22, 2025

Related U.S. Application Data
(63) Continuation of application No. PCT/CN2022/139583, filed on Dec. 16, 2022.

(30) Foreign Application Priority Data
Dec. 6, 2022 (CN) 202211556659.6

(51) Int. Cl. H05K 7/20; H05K 7/14

(52) U.S. Cl. CPC H05K 7/2079; H05K 7/1497; H05K 7/20236

(57) ABSTRACT

The present invention discloses an underwater data center comprising a pressure-resistant cabin, an outer framework, a lifting mechanism, a pipeline system, internally disposed server cabinets, a maintenance elevator mechanism, a stationary and mobile mechanism, and an internal state monitoring system. The pressure-resistant cabin constitutes a sealed structure formed by the pressure-resistant enclosure, featuring at least one access on its surface. The lifting mechanism includes hydraulic jack and lifting guide post. Server cabinets are arrayed within the pressure-resistant enclosure and are secured and maneuvered using the stationary and mobile mechanism at both upper and lower ends. This innovation enables efficient surfacing and submerging operations, making it particularly adaptable for large-scale, high-density data center systems requiring stable underwater cooling. The cabin entrance facilitates inspections and repairs, thereby enhancing operational efficiency. The integrated monitoring system ensures superior environmental security through real-time status surveillance and prompt risk identification capabilities.

### CROSS-REFERENCE TO RELATED APPLICATIONS

The present application is a continuation of International Application No. PCT/CN2022/139583, filed on Dec. 16, 2022, which claims priority to Chinese Patent Application No. 202211556659.6, filed on Dec. 6, 2022, the entire disclosure of which is incorporated herein by reference.

### TECHNICAL FIELD

The present invention relates to the field of heat exchange technologies, and more particularly to an underwater data center.

### BACKGROUND

Data centers are an essential infrastructure for mobile data, cloud computing, and big data services. As data center scale continues to expand, the density of individual server cabinets increases accordingly, which leads to a significant rise in the heat generated by the equipment's chips. Consequently, effective cooling of data centers has become a persistent and critical issue in the field. With continuous technological advancement, current trends in data center cooling technologies include: localized end-point cooling closer to the servers; direct fresh-air cooling; and using deep lake or river water for cooling. Among these, the most energy-efficient and effective approach is the underwater data center, which utilizes lake or river water for direct cooling without the need for mechanical refrigeration, enabling the data center to maintain a stable temperature below 10° C.

Some prior technologies relating to underwater data centers have been disclosed, such as an underwater data center cooling apparatus and an underwater data center comprising the same. These typically employ cooling pipelines with water pumps and heat exchange modules to achieve thermal exchange with the data center body. However, in the event of malfunction, such systems require the deployment of divers for retrieval and maintenance, lacking features for direct internal maintenance access and real-time internal condition monitoring. Similarly, other technologies, such as certain underwater data centers, are comprised of only a small number of standalone cabinets, forming compact systems that do not support internal maintenance, automatic surfacing for repair, or internal state real-time monitoring. For large-scale data centers composed of high-density standalone server cabinets, existing underwater center technologies fail to provide efficient and scalable solutions.

### SUMMARY OF THE INVENTION

The present invention provides an underwater data center designed to address the aforementioned issues.

To achieve this objective, the underwater data center provides technical solution as follows:
The underwater data center as described in the present invention comprises a pressure-resistant cabin, an outer framework, a lifting mechanism, a pipeline system, internally disposed server cabinets, a maintenance elevator mechanism, a stationary and mobile mechanism, and an internal state monitoring system;
The pressure-resistant cabin is formed as a sealed structure by the pressure-resistant enclosure, featuring at least one access on its surface;
The outer framework includes a bottom support frame fixedly connected to the pressure-resistant enclosure, enclosure side reinforcing ribs, and the lifting mechanism mounting bracket.

The lifting mechanism includes hydraulic jack and lifting guide post installed via the lifting mechanism mounting bracket.
The pipeline system includes the hydraulic pipeline and main power signal conduit sealedly extending from within the pressure-resistant enclosure, and wiring troughs positioned at the bottom inside the pressure-resistant enclosure beneath the server cabinets;
The maintenance elevator mechanism, located directly below the pressure-resistant cabin access, includes an elevator connected to a foldable floor that moves vertically;
The server cabinets are arranged in an array within the pressure-resistant enclosure, secured and maneuvered by the stationary and mobile mechanism at both upper and lower ends. Servers are arrayed within the cabinets via bracket mounting plates and server bracket mounting screws;
The stationary and mobile mechanism includes servo guide rails positioned between the top and bottom inside the pressure-resistant enclosure, servo rail sliders that allow the server cabinets to slide laterally along the servo rails, and an electric propulsion system;
The internal state monitoring system includes camera and/or temperature, humidity, oxygen, and hydrogen sensor controller installed within the pressure-resistant enclosure.

Further, the pressure-resistant cabin access includes the outer flange fixed and sealed via outer flange nuts, the first sealing gasket, and the external waterproof flange cover.

Further, the pressure-resistant cabin access includes the inner flange on the top of the pressure-resistant enclosure, the second sealing gasket, and the inner manhole sealing flange, all fixed and sealed with internal flange bolts.

Further, the inner manhole closure flange is provided with a nitrogen-injection and exhaust valve cluster mounted in an internal recess. The said valve cluster includes a shut-off valve communicating with the pressure-resistant cabin, an exhaust valve positioned above the shut-off valve, and a valve chamber sealing cover.

Further, a manually openable manhole chamber is installed above the external waterproof flange cover, with safety guardrails and maintenance anti-slip plates positioned at the front of its entrance; The manhole chamber is equipped with a waterproof manhole door operated by a gate handwheel.

Further, a first support rib is disposed between the outer flange bottom of pressure-resistant cabin and the pressure-resistant enclosure, featuring conduit holes on its side for routing hydraulic pipelines.

Further, one end of the hydraulic pipeline is connected to the hydraulic jack via hydraulic jack joint, while the other end is connected to a hydraulic distribution valve.

Further, the pressure-resistant enclosure is formed by hermetically welding a single or multiple sealed pressure-resistant plates, with pressure-resistant side ribs on both sides.

Further, the bottom support frame includes forklift holes and an internal second support rib fixedly connected to the pressure-resistant enclosure;
Positioning holes for pipeline routing are available in the side reinforcing ribs, and an anti-slip plate mounting bracket is mounted at the top of the side ribs via mounting bolts. The anti-slip plate mounting bracket is fixedly connected to the maintenance anti-slip plate via anti-slip plate bolts.

Further, the lifting mechanism mounting bracket includes the X-shaped support used to connect two sets of lifting guide posts and first welding plate lugs on the sides of the hydraulic jack via positioning bolts, and the second welding plate lug connected to lifting frame mounting lugs at both ends of the pressure-resistant enclosure via lifting frame mounting bolts.

Further, a mounting base is respectively welded to the jacking head end of the hydraulic jack and to the bottom of the hollow shaft of the guide frame within the lifting guide post. The mounting base is fixedly secured to an I-beam base via guide frame bolts.

Further, the lifting guide post includes a guide frame outer sleeve, a drainage pipe disposed within the outer sleeve, and a hollow shaft disposed with a clearance fit inside the drainage pipe. Both ends of the drainage pipe wall are formed with through-type drainage holes. An extension aperture is formed at the top of the outer sleeve such that the sleeve is longer than the hollow shaft, and a main guide frame shaft positioning ring is disposed within the extension aperture for limiting displacement.

Further, the main power signal conduit is connected to a primary conduit extending upward from the pressure-resistant enclosure, and its top is fastened to the upper end of the openable manhole chamber via S-adapter nut. The uppermost portion of the conduit is formed in an upward-facing S-bend configuration, beneath which a waterproof drainage hole is provided.

Further, the servo rails and the electric propulsion structure are laterally installed on the mounting ribs disposed at both the inner top of the pressure-resistant outer shell and the inner bottom of the pressure-resistant inner shell; the electric propulsion structure includes two parallel linear actuator assemblies, an actuator housing, and propeller locking lugs arranged in a figure-eight pattern within the actuator housing, wherein interconnection is achieved by a propeller locking pin penetrating both cabinet locking lugs at the server rack base and said propeller locking lugs.

Further, an internal LED light strip is installed on the mounting rib at the top interior of the pressure-resistant enclosure.

Further, the cameras and temperature-humidity-oxygen-hydrogen sensor controllers are installed on the mounting ribs located at the inner top of the pressure-resistant enclosure.

Further, a compensating air conditioner is installed on the inner sidewall of the pressure-resistant cabin.

Further, an intelligent control cabinet is provided inside the pressure-resistant cabin. The intelligent control cabinet is equipped with a smart display control system, multiple intelligent circuit breakers, an optical fiber splitter, an optical core switch, and a power distribution unit PDU.

Further, a liftable cargo rack may be installed on the floor.

Further, a storage box is installed within the openable manhole chamber.

Further, the both sides of the pressure-resistant enclosure may be formed in polyhedral shapes, including tetrahedral, dodecahedral, or hexadecagonal configurations.

Further, the server cabinets movable via the stationary and mobile mechanism may include monolithic server cabinets or modular multi-unit server cabinets, with the latter including configurations such as three-unit server cabinets.

Further, the underwater data center can be configured, depending on its mode of application, as a fully submersible data center or a semi-submersible data center.

The present invention provides the following advantages over the prior art:
(1) The underwater data center of the present invention can be configured as either a fully submersible or semi-submersible system. The semi-submersible configuration allows for maintenance access without the need to surface the unit, while the fully submersible configuration is equipped with an integrated lifting mechanism enabling efficient emergence from water, facilitating technician access and maintenance operations;
(2) The underwater data center achieves efficient surfacing and submergence operations through its integrated lifting mechanism, eliminating dependence on external forces beyond its structural configuration;
(3) The pressure-resistant cabin exhibits superior structural integrity with optimized connection strength and stability to the outer framework, featuring scalable dimensions adaptable to large-volume, high-density data center systems for underwater thermal management;
(4) The system is configured with pressure-resistant cabin access, openable manhole chamber, and maintenance lifting structure, which enable maintenance operations without cabin surfacing. The internal server cabinets are easily repositionable, conducive to enhancing operational and utilization efficiency, and maintaining a stable internal temperature;
(5) A real-time internal state monitoring system is deployed within the pressure-resistant cabin, which is capable of collecting data such as internal temperature, humidity, oxygen levels, and video feed, thereby ensuring environmental safety and early risk detection.

(6) The presence of the maintenance elevator mechanism, safety guardrails, and an openable manhole chamber enables fast, convenient, and safe maintenance procedures.

It should be noted that the realization of any given product embodiment of the present invention does not necessarily require the attainment of all the stated advantages simultaneously.

### BRIEF DESCRIPTION OF THE DRAWINGS

To clarify the technical solutions of the embodiments under the present invention, the drawings required for the description of the embodiments are briefly introduced below. Evidently, the drawings described below are merely some of the embodiments of the present invention. Those skilled in the art may derive additional illustrations from these drawings without creative efforts.

FIG. 1 is a schematic structural diagram of the embodiment 1 of the underwater data center according to the present invention;

FIG. 2 is an enlarged partial view of position A in FIG. 1;

FIG. 3 is a left side view of the structure shown in FIG. 1;

FIG. 4 is a right side view of the structure shown in FIG. 1;

FIG. 5 is a top plan view of the structure shown in FIG. 1;

FIG. 6 is an enlarged partial view of position B in FIG. 5;

FIG. 7 is an enlarged partial view of position C in FIG. 5;

FIG. 8 is an exploded view of the structure shown in FIG. 1;

FIG. 9 is a schematic view from perspective D of FIG. 8;

FIG. 10 is a scenario diagram of the underwater data center in operation according to FIG. 1;

FIG. 11 is a scenario diagram of the underwater data center in FIG. 1 after being elevated for external component maintenance of the pressure-resistant enclosure;

FIG. 12 is a side view of a dodecahedral pressure-resistant enclosure;

FIG. 13 is a side view of a tetrahedral pressure-resistant enclosure;

FIG. 14 is a side view of a hexadecahedral pressure-resistant enclosure;

FIG. 15 is a schematic structural diagram of the embodiment 2 of the underwater data center according to the present invention;

FIG. 16 is a top plan view of the structure shown in FIG. 15;

FIG. 17 is a left side view of the structure shown in FIG. 15;

FIG. 18 is a bottom view of the structure shown in FIG. 15;

FIG. 19 is an exploded view of the structure shown in FIG. 15;

FIG. 20 is a schematic view from perspective E of FIG. 19;

FIG. 21 is a scenario diagram of the underwater data center in operation according to the embodiment 2;

FIG. 22 is a scenario diagram of the underwater data center in the embodiment 2 during internal maintenance after elevation;

FIG. 23 is a schematic structural diagram of the underwater data center in the embodiment 3 according to the present invention;

FIG. 24 is a top plan view of the structure shown in FIG. 23;

FIG. 25 is a sectional view taken along line F-F of FIG. 24;

FIG. 26 is an enlarged partial view of position H in FIG. 25;

FIG. 27 is an enlarged partial view of position Q in FIG. 25;

FIG. 28 is a sectional view taken along line G-G of FIG. 25;

FIG. 29 is an enlarged partial view of position R in FIG. 28;

FIG. 30 is a structural view showing the elevator base plate in its unfolded state with the elevator rack installed;

FIG. 31 is a sectional view taken along line I-I of FIG. 25;

FIG. 32 is a sectional view taken along line J-J of FIG. 25;

FIG. 33 is a sectional view taken along line K-K of FIG. 25;

FIG. 34 is an enlarged partial view of position S in FIG. 33;

FIG. 35 is a sectional view taken along line L-L of FIG. 25;

FIG. 36 is a sectional view taken along line M-M of FIG. 25;

FIG. 37 is a sectional view taken along line N-N of FIG. 25;

FIG. 38 is a sectional view taken along line O-O of FIG. 25;

FIG. 39 is a sectional view taken along line P-P of FIG. 25;

FIG. 40 is an enlarged partial view of position T in FIG. 39;

FIG. 41 is an enlarged partial view of position U in FIG. 39;

FIG. 42 is an enlarged partial view of position V in FIG. 39;

FIG. 43 is an exploded view of the propulsion mechanism of the monolithic server cabinet;

FIG. 44 is an exploded view of the propulsion mechanism of the multi-cabinet server system;

FIG. 45 is a schematic structural diagram of the underwater data center in the embodiment 4 according to the present invention;

FIG. 46 is a system block diagram of the present invention.

### LIST OF REFERENCE NUMERALS IN THE DRAWINGS

1—Pressure-resistant enclosure; 101—Side shell reinforcing rib; 1011—Pipe position limiting hole; 102—Forklift slot; 103—Second support rib; 104—I-beam base; 106—First support rib; 107—X-shaped bracket; 108—Bottom support frame; 109—Pressure-resistant top cover; 1091—Mounting rib; 1093—Inner manhole sealing flange; 1094—Second sealing gasket; 1095—Inner flange of pressure-resistant enclosure; 1096—Inner flange bolt; 110—Lateral rib of pressure-resistant enclosure; 2—hydraulic jack; 201—Hydraulic cylinder fitting; 202—Hydraulic pipeline; 203—Hydraulic distribution valve; 204—X-bracket positioning bolt; 2041—First welded plate lug; 2042—Lift frame mounting lug; 2043—Lift frame mounting bolt; 2044—Second welded plate lug; 205—Mounting base; 206—Guide frame bolt; 207—lifting guide post; 2071—Guide frame drainage pipe; 2072—Extended hole; 2073—Primary guide shaft locating ring; 2074—Hollow guide shaft; 2075—Outer guide shaft sleeve; 2076 Drainage port; 3—Main conduit; 301—First sealing gasket; 302—Main power signal conduit; 3031—S-adapter nut; 3032—Waterproof drainage hole; 4—Openable manhole chamber; 401—Maintenance anti-slip plate; 402—Safety guard rail; 403—Waterproof manhole cover; 404—Gate valve handwheel; 405—Anti-slip plate mounting bracket; 4051—Mounting bolt of anti-slip plate frame; 406—Outer flange nut; 407—Outer waterproof flange cover; 408—Outer flange of pressure-resistant cabin; 409—Storage box; 5—Server rack; 501—Rack mounting plate; 502—Server mounting screw; 503—Server; 6—Compensating air conditioner; 601—Lighting strip; 602—Temperature-humidity-oxygen-hydrogen sensor controller; 603—Propeller locking pin; 604—Propeller locking lug; 7—Elevator; 701—Floor plate; 702—Elevator rack; 8—Servo guide slider; 801—Servo guide rail; 802—Cable tray; 803—Electric propulsion structure; 8031—Linear actuator assembly; 8032—Actuator housing; 9—Intelligent control cabinet; 901—Intelligent display control system; 902—Intelligent circuit breaker; 903—Optical splitter; 904—Optical core switch; 905—Power distribution unit PDU; 906—Nitrogen injection and exhaust valve manifold; 9061—Shut-off valve; 9062—Exhaust valve; 9063—Valve chamber sealing cover.

### DETAILED DESCRIPTION

The technical solutions in the embodiments of the present invention are clearly and completely described below in conjunction with the accompanying drawings. It should be expressly noted that the described embodiments are merely exemplary and not exhaustive. All other embodiments obtained by persons of ordinary skill in the art based on the embodiments herein without creative efforts shall fall within the protection scope of the present invention.

As used herein, directional terms such as “inner,” “surface,” “bottom,” “inner bottom,” “lower,” “lateral,” “upper,” etc., are used for convenience of description and are not intended to limit the positioning, orientation, or operational relationships of the components. These terms shall not be construed as limiting the scope of the present invention.

The underwater data center according to the present disclosure may be configured either a fully-submerged fully-submersible configuration or a semi-submerged semi-submersible configuration, depending on its deployment mode.

### Embodiment 1

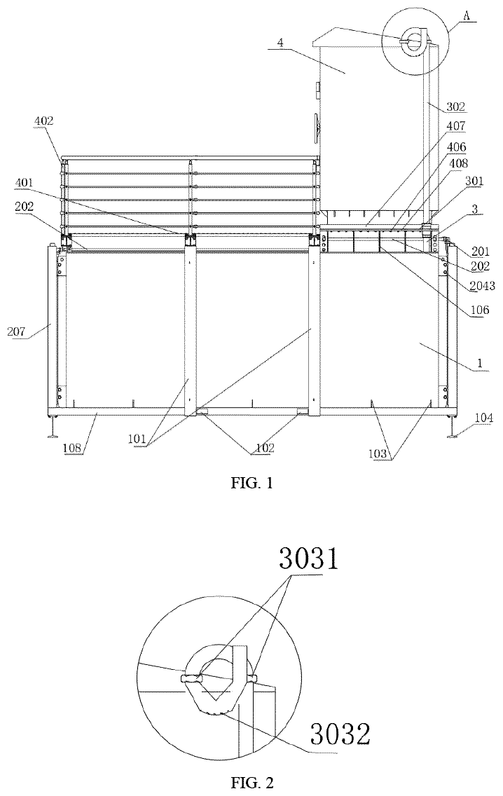

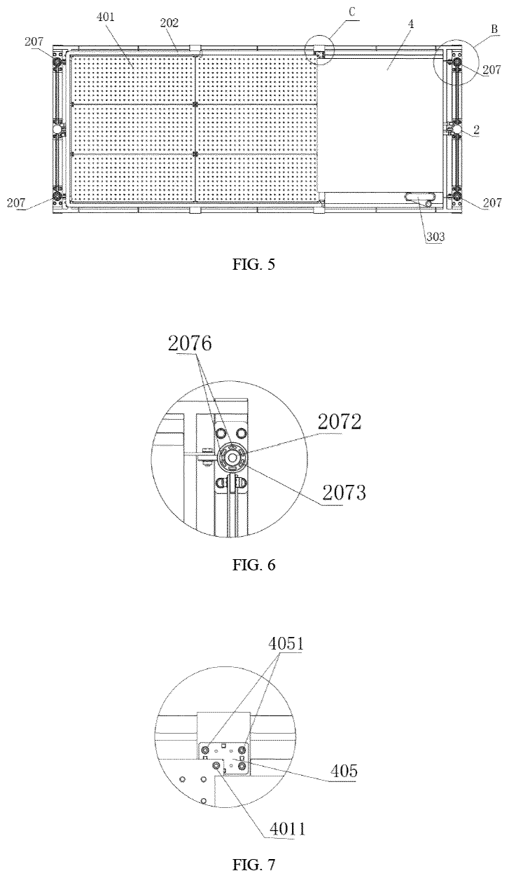

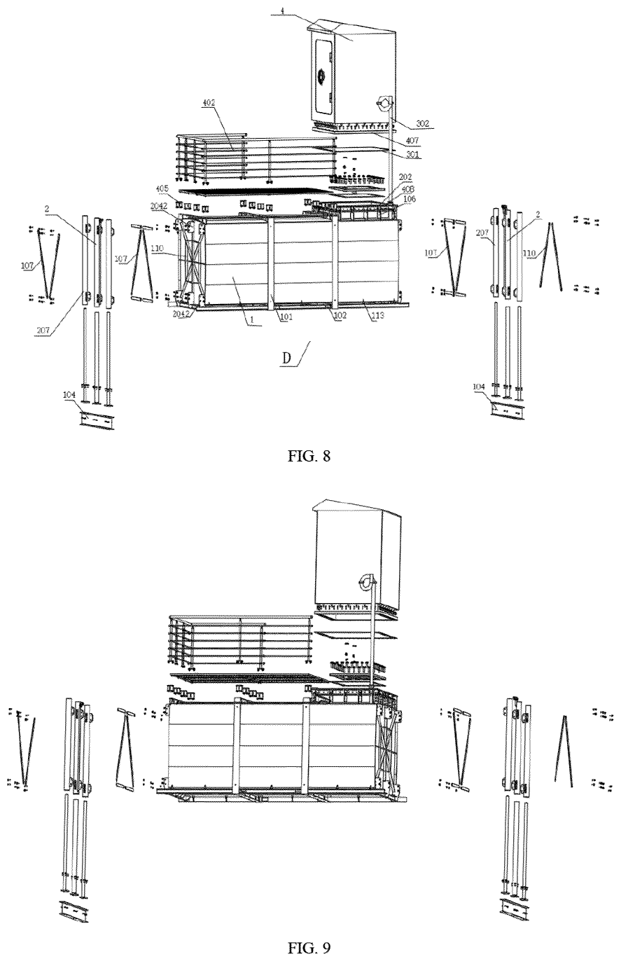

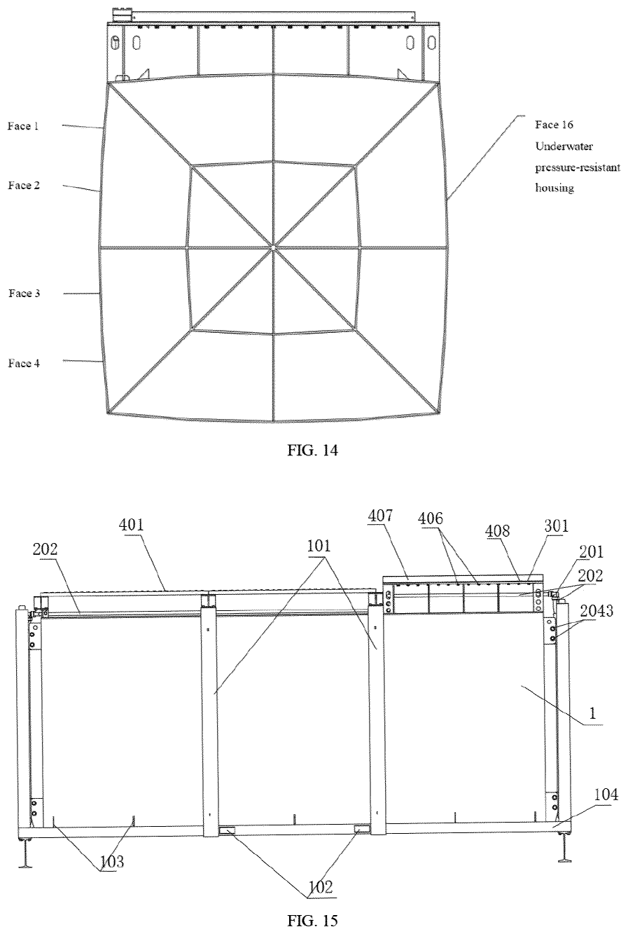

Referring to FIGS. 1-14, this embodiment discloses a semi-submersible underwater data center, detailing its external structure, which includes a pressure-resistant cabin, an outer framework, a lifting mechanism, and a pipeline system.
The pressure-resistant cabin is formed as a sealed structure by the pressure-resistant enclosure 1, featuring at least one access on its surface;
The outer framework includes a bottom support frame 108 fixedly connected to the pressure-resistant enclosure 1, enclosure side reinforcing rib 101, and lifting mechanism mounting bracket; The lifting mechanism includes hydraulic jack 2 and lifting guide post 207 installed via the lifting mechanism mounting bracket;

The pipeline system includes the hydraulic pipeline 202 and main power signal conduit 302 sealedly extending from within the pressure-resistant enclosure 1.

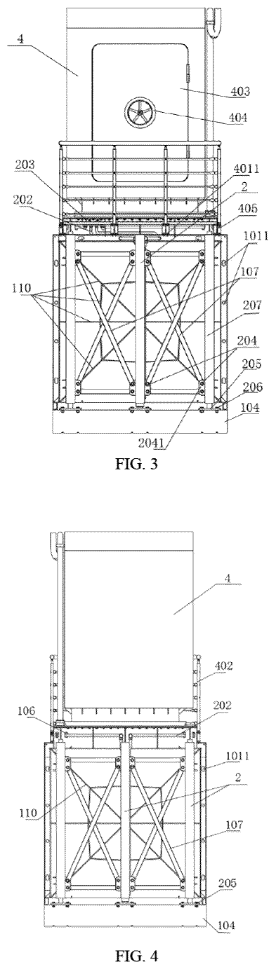

As shown in FIGS. 1 and 3, the openable manhole chamber 4 is mounted atop the external waterproof flange cover 407, with safety guardrail 402 and maintenance anti-slip plate 401 installed at the front of the manhole chamber 4 entrance. The manhole chamber 4 features a waterproof manhole door 403 operated by rotating gate handwheel 404. Maintenance personnel can access the manhole chamber 4 by turning the gate handwheel 404 to open the waterproof manhole door 403 and then enter the interior of the pressure-resistant cabin through the access. The surface of the maintenance anti-slip plate 401 is designed with anti-slip patterns or protrusions.

As depicted in FIGS. 1 and 3, each long side of the pressure-resistant enclosure 1 is equipped with two side shell reinforcing ribs 101. One end of the side shell reinforcing rib 101 supports the installation of the openable manhole chamber 4 via anti-slip plate mounting bracket 405, while the other end supports the safety guardrail 402 via another anti-slip plate mounting bracket 405, forming the data center structure shown in FIG. 1. The side shell reinforcing rib 101 is specifically made of T-shaped or L-shaped angle steel.

The pressure-resistant cabin access includes an external pressure-resistant cabin flange 408 secured and sealed via outer flange nut 406, first sealing gasket 301, and external waterproof flange cover 407.

The first support rib 106 is positioned between the bottom of the external pressure-resistant cabin flange 408 and the pressure-resistant enclosure 1, with conduit hole 1061 on its side for routing the hydraulic pipelines 202.

One end of the hydraulic pipeline 202 connects to the hydraulic jack 2 via hydraulic jacket joint 201, while the other end connects to a hydraulic distribution valve 203, controlled by an intelligent control cabinet 9 located inside the pressure-resistant cabin, as shown in FIG. 2.

The pressure-resistant enclosure 1 is formed through integral welding of a single pressure-resistant plate or hermetic welding of multiple pressure-resistant plates, with lateral ribs 110 on both sides. In this embodiment, the enclosure the pressure-resistant 1 constituting pressure-resistant cabin is a sealed rectangular box structure welded from integral steel plates for the sides, top, and bottom. The pressure-resistant enclosure side ribs 110 are arranged in a “ [symbol] <” shape with a central “□” shape. The length-to-width ratio of the box structure is approximately 5:3, and the width-to-height ratio is about 1:1.

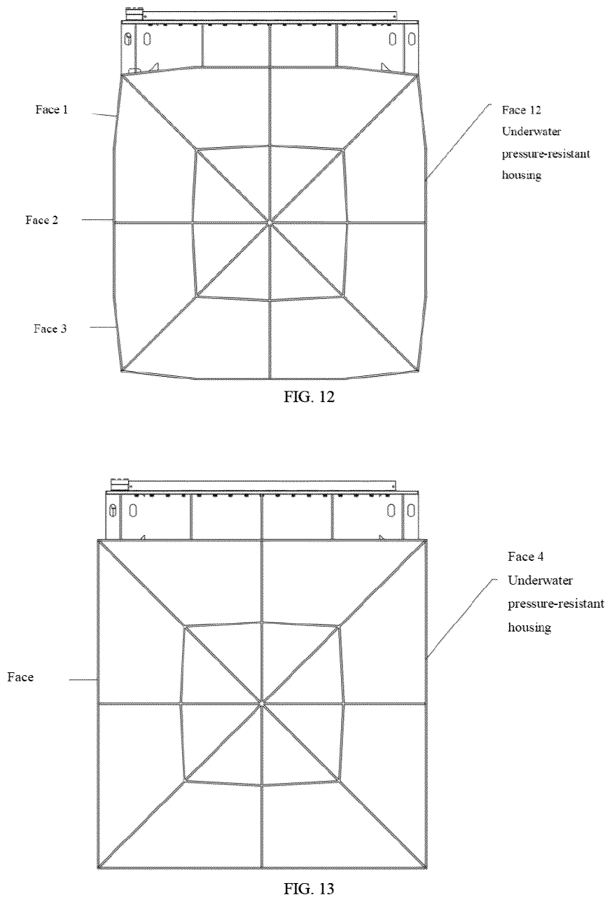

As illustrated in FIGS. 12-14, the specific shapes of both sides of the pressure-resistant enclosure 1 include tetrahedral, dodecahedral, and hexadecahedral forms. The tetrahedral shape has rectangular sides; the dodecahedral shape has sides approximating rectangles with three edges; and the hexadecahedral shape has sides approximating rectangles with four edges. All are constructed by sealing and welding prefabricated plates.

The bottom support frame 108 features forklift hole 102 and internally includes second support rib 103 fixedly connected to the pressure-resistant enclosure 1, facilitating land transportation via forklift.

The side shell reinforcing rib 101 is equipped with pipe position limiting hole 1011 to secure the hydraulic pipelines 202. The top of the side shell reinforcing rib 101 is provided with anti-slip plate mounting bracket 405 fastened by anti-slip plate mounting bracket bolt 4051, with the anti-slip plate mounting bracket 405 and maintenance anti-slip plate 401 connected via anti-slip plate bolt 4011.

As shown in FIGS. 3-9 and 17, the lifting mechanism mounting bracket includes X-shaped support 107 connecting two sets of lifting guide posts 207 and the sides of the hydraulic jack 2 via first welded plate lugs 2041 and X-shaped support positioning bolts 204. The second welded plate lug 2044 is connected to the lifting frame mounting lug 2042 on both ends of the pressure-resistant enclosure 1 via lifting frame mounting bolts 2043. Each side of the X-shaped supports 107 has two sets, connecting the first welded plate lugs 2041 on both sides of the hydraulic jacks 2 and the sides of the lifting guide posts 207 with X-shaped support positioning bolts 204. This ensures stability and structural strength during the overall lifting of the pressure-resistant cabin by the hydraulic jack 2, and facilitates assembly and disassembly.

The base end of the lifting head of hydraulic jack (2) and the lower portion of guide frame hollow shaft 2074 within lifting guide post 207 are each welded with mounting bases 205). The said mounting base (205) is fixedly mounted to I-beam base (104) via guide frame bolts (206).

Referring to FIGS. 1-3, the main power signal conduit 302 is connected to the main conduit 3 extending from the upper portion of the pressure-resistant enclosure 1. The top end of the main power signal conduit 302 is connected to the upper end of the openable manhole chamber 4 via S-adapter nut 3031. The top of the main power signal conduit 302 is formed in an upward-facing S-bend configuration, with waterproof drain hole 3032 provided beneath the curvature of the S-bend to prevent water ingress.

As shown in FIG. 8, an exploded view of the semi-submersible underwater data center of the present embodiment is illustrated, clearly depicting the structural configuration and the positional and connection relationships among components. FIG. 9 presents an exploded view from the D-direction indicated in FIG. 8.

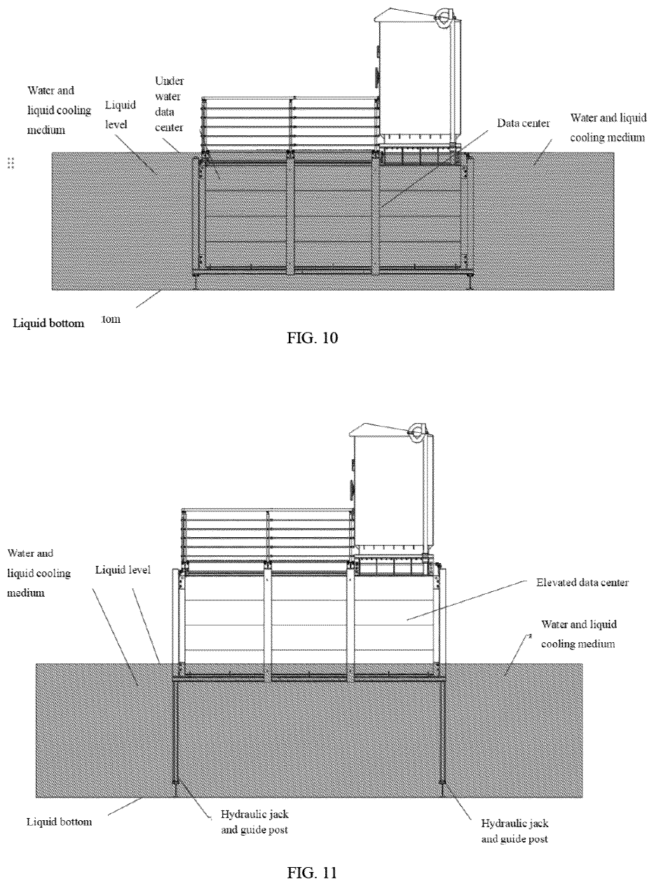

As illustrated in FIGS. 10-11, the vertical motion of the pressure-resistant cabin during operation is stably controlled via the hydraulic jack 2 and the lifting guide post 207. The pressure-resistant cabin may be lowered below the water surface, with only the openable manhole chamber 4 remaining above the liquid level of water or liquid coolant. This configuration allows maintenance personnel to access the interior of the pressure-resistant cabin for servicing without fully removing the cabin from the water, thereby enabling efficient inspection and maintenance. Upon elevation, the manhole chamber 4 allows direct entry by maintenance personnel into the cabin to service the servers, eliminating the need for external lifting equipment and thereby simplifying the maintenance process. Moreover, when the pressure-resistant enclosure 1 and its associated external components of the semi-submersible data center require servicing, the entire cabin can be lifted above the liquid level by the hydraulic jack 2 and lifting guide post 207, thereby exposing the sidewalls of the pressure-resistant enclosure 1 for both internal and external maintenance. Internal inspection can be performed without disrupting the equilibrium of the internal environment, improving operational efficiency. The top of the main power signal conduit 302 remains continuously positioned above the water level, and its S-bend design combined with the waterproof drainage hole 3032 effectively prevents water ingress through the conduit 302.

### Embodiment 2

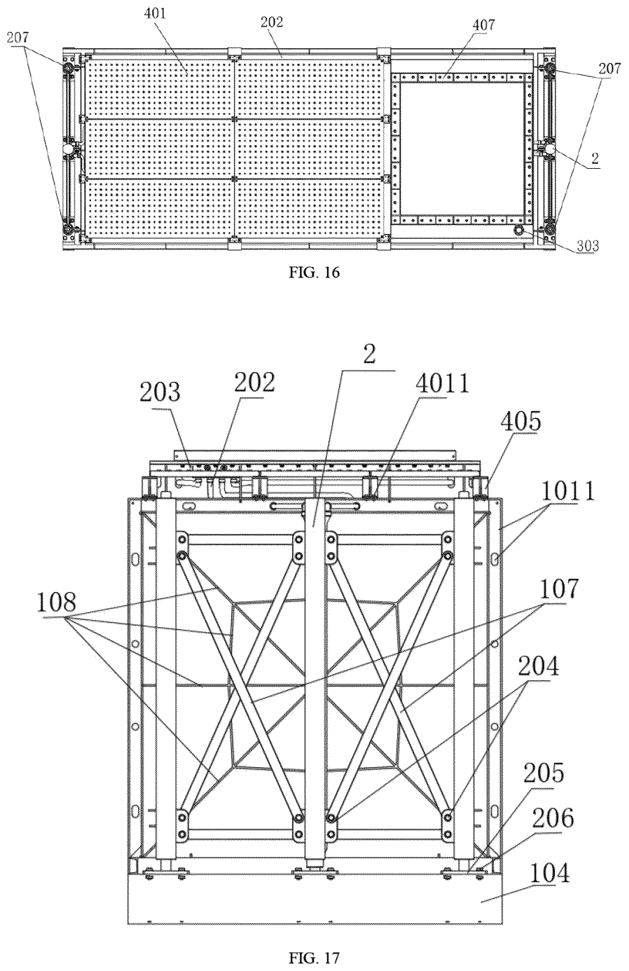

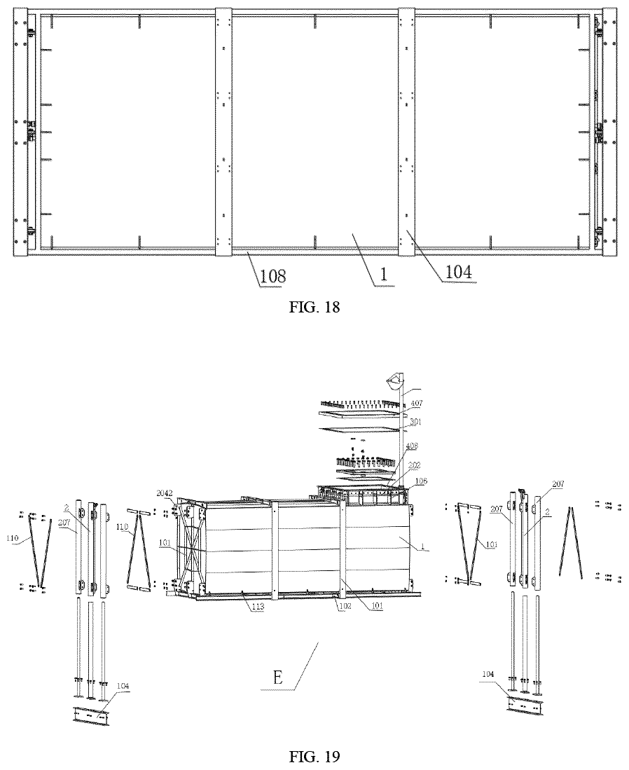

Referring to FIGS. 15-22, this embodiment discloses a fully submersible underwater data center. In contrast to the Embodiment 1, the present embodiment omits the openable manhole chamber 4, safety guardrail 402, and the corresponding mounting structure.

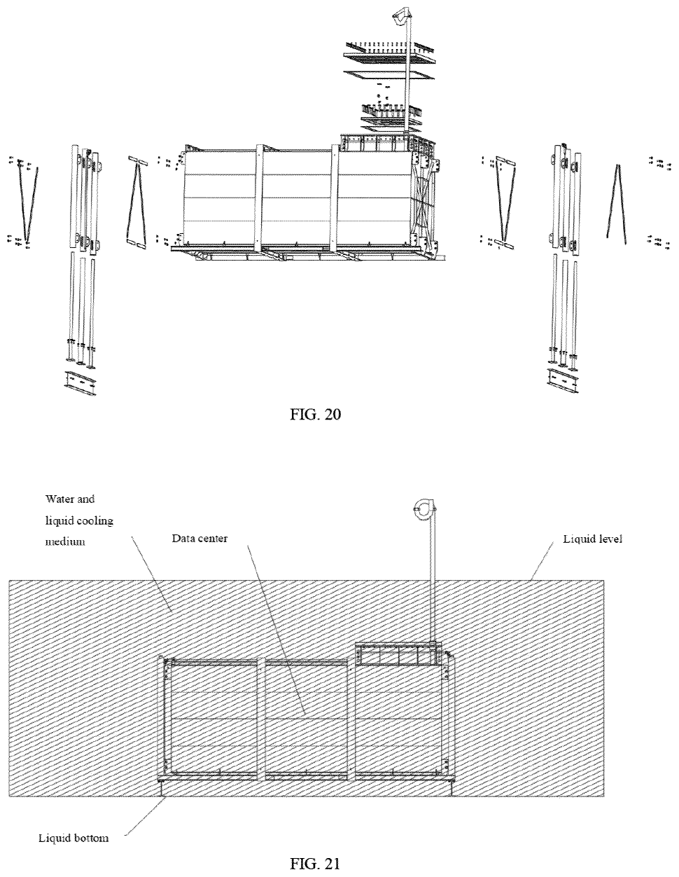

FIG. 19 illustrates an exploded view of the structural configuration of the fully submersible data center, clearly revealing the component layout and spatial relationships. FIG. 20 shows an exploded view from the E-direction in FIG. 19.

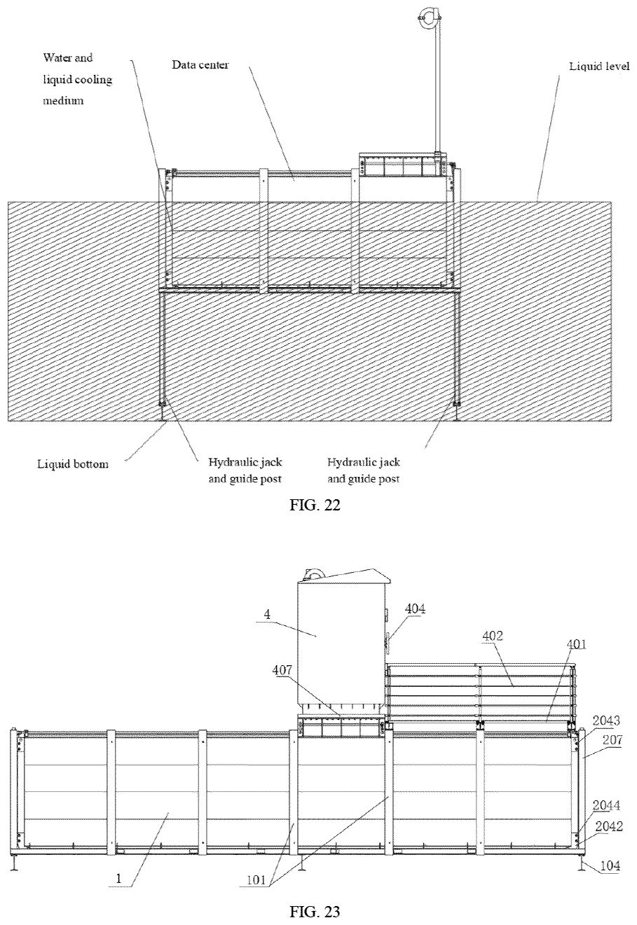

As shown in FIGS. 21-22, the vertical motion of the pressure-resistant cabin during operation is stably controlled via the hydraulic jack 2 and the lifting guide post 207, allowing the data center to be fully submerged below the water or liquid coolant level. The structural configuration, including the external waterproof flange cover 407, prevents water ingress into the pressure-resistant cabin. When the maintenance is required, pressure-resistant cabin is elevated above the liquid level using the hydraulic jacks 2 and lifting guide posts 207, exposing the maintenance anti-slip plate 401 and the waterproof flange cover 407. Access to the cabin interior is gained by removing the external waterproof flange cover 407 via the cabin access. Notably, the fully submersible data center does not require any external lifting force beyond its built-in lifting mechanism, allowing for efficient surfacing and submersion as needed.

### Embodiment 3

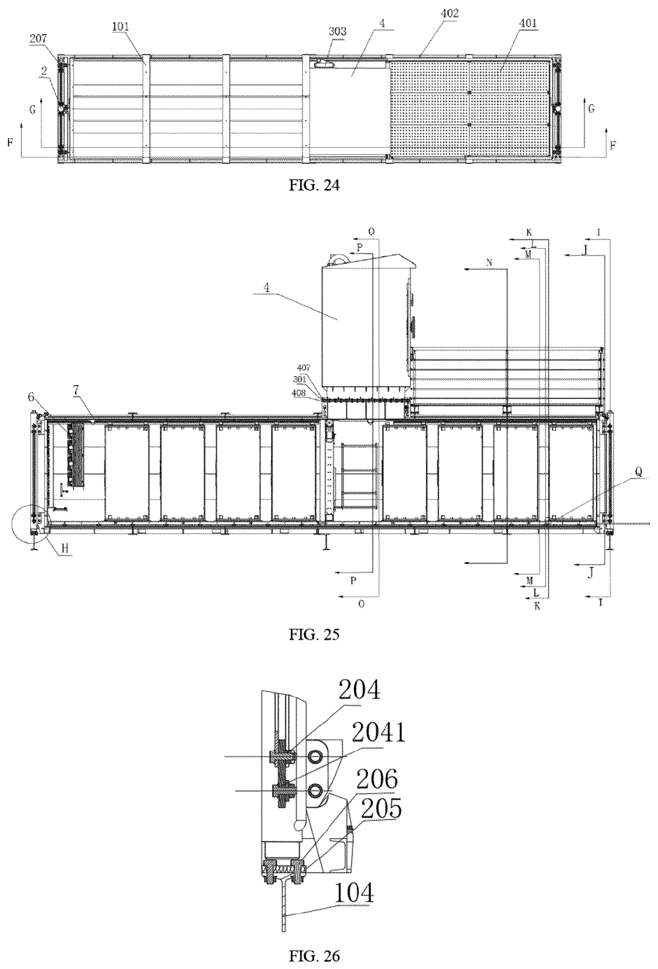

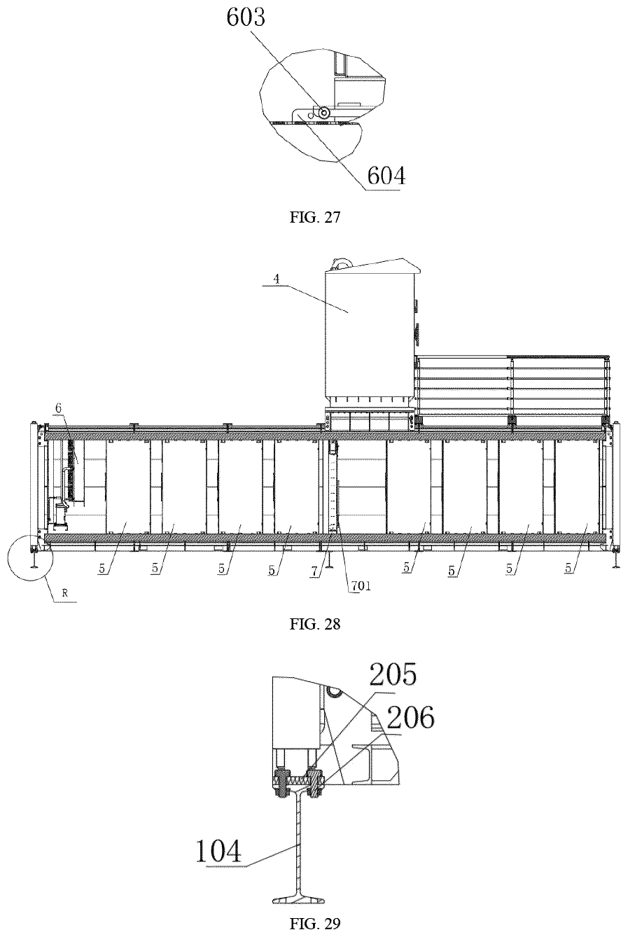

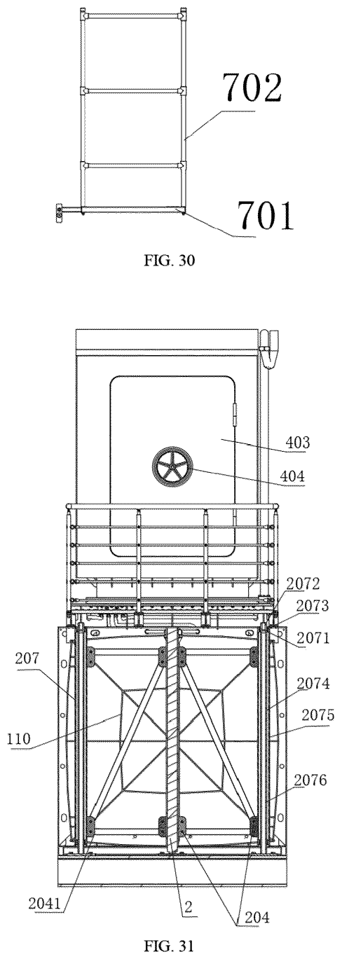

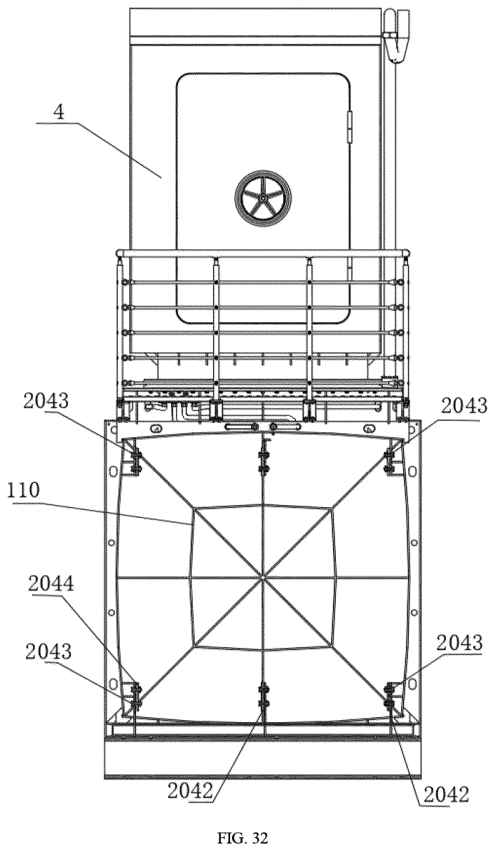

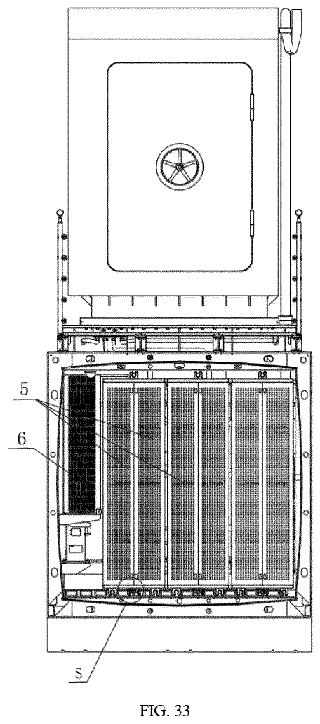

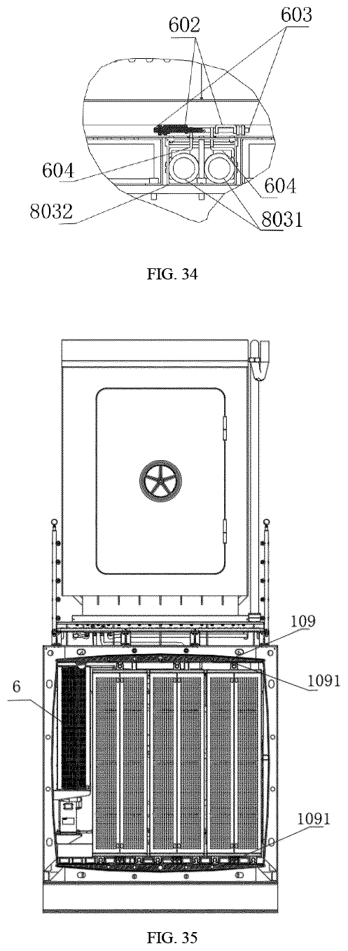

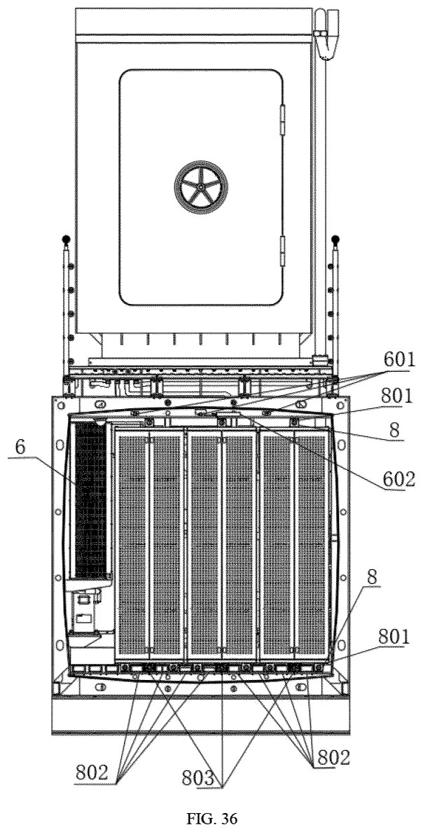

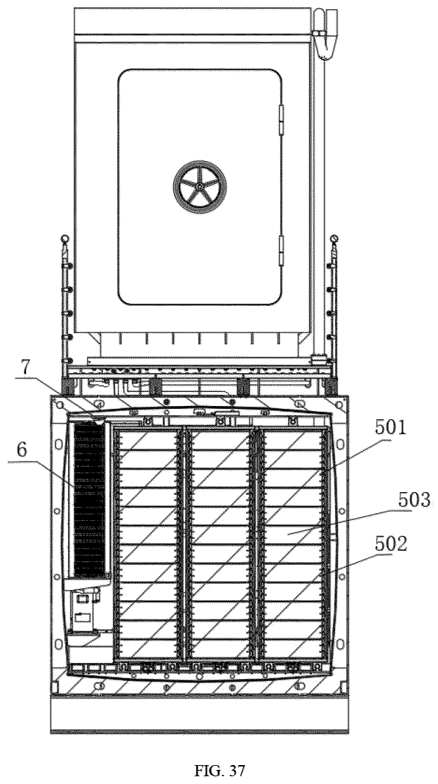

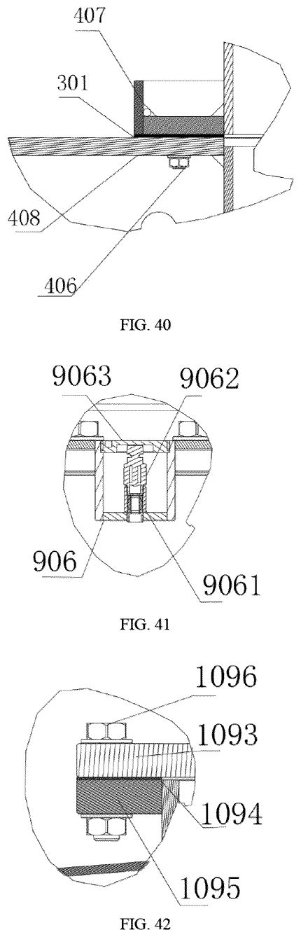

Referring to FIGS. 23-44 and FIG. 46, this embodiment also discloses a semi-submersible underwater data center. In contrast to the Embodiment 1, this embodiment additionally reveals the internal server rack 5, maintenance elevator mechanism, stationary and mobile mechanism, and internal state monitoring system located within the pressure-resistant enclosure 1. The internal state monitoring system includes one or more cameras 7 and/or temperature-humidity-oxygen sensors 602 mounted inside the pressure-resistant enclosure 1. In the present embodiment, both the camera 7 and the temperature-humidity-oxygen sensor controller 602 are included.

FIG. 23 shows that each long side of the pressure-resistant enclosure 1 is provided with five side shell reinforcing ribs 101. The openable manhole chamber 4 is installed between the second and third side shell reinforcing ribs 101 via anti-slip plate mounting brackets 405. The safety guardrail 402 is installed between the first and second reinforcing ribs 101 and the adjacent outermost reinforcing rib via additional anti-slip plate mounting bracket 405, forming the data center structure shown in FIG. 23. The side shell reinforcing ribs 101 are formed from T-section or L-section angle steel.

This embodiment encompasses camera 7 and a temperature-humidity-oxygen-hydrogen sensor controller 602. The temperature-humidity-oxygen-hydrogen sensor controller 602 functions as follows: The temperature sensor monitors the internal temperature of the data center; the humidity sensor monitors internal humidity and the presence of trace water ingress; the oxygen sensor monitors the oxygen concentration within a nitrogen-filled environment to detect possible leakage; and the hydrogen sensor detects hydrogen concentration, which may be released from battery decomposition in the event that an internal UPS is installed. During normal operation, the data center is filled with nitrogen, maintaining an oxygen-free and moisture-free internal environment.

The pressure-resistant enclosure 1 forming the pressure-resistant cabin in this embodiment is a sealed rectangular box-type structure composed of side, top, and bottom panels welded together in a segmented fashion using steel plates. The hydraulic piping 202 further includes a cable trough 802 disposed on the bottom interior of the pressure-resistant enclosure 1 and located beneath the server cabinets 5, allowing for wiring to connect the server cabinets 5 with the intelligent control cabinet 9, and to further connect with the main power signal conduit 302.

A maintenance elevator mechanism is located directly below the cabin access and comprises the elevator 7 and foldable platform 701 that is operably connected to the elevator 7 for lifting and lowering operations. The lift rack 702 may be installed on the platform 701. The platform 701 is foldably connected to the elevator 7 using a hinged structure such that, when folded, the platform 701 rests against the side of the elevator 7, forming the structure shown in FIG. 17; in the deployed state, it assumes the configuration shown in FIG. 19. The spliced lift rack 702 installed on the platform 701 facilitates cargo and personnel handling during elevation to ensure safety.

As shown in FIGS. 25-44, the server cabinets 5 are arranged in an array within the pressure-resistant enclosure 1 and are controlled for positioning and movement by the stationary and mobile mechanism installed at the top and bottom ends. Each server 503 is mounted inside the server cabinet 5 via mounting bracket 501 and server mounting screw 502.

The stationary and mobile mechanism includes the servo guide rail 801 extending between the top and bottom inside the pressure-resistant enclosure 1, the servo guide rail slider 8 that connects the server cabinet 5 for transverse movement along the servo guide rail 801, and the electric propulsion structure 803.

The servo guide rail 801 and the electric propulsion structure 803 are horizontally mounted to the mounting ribs 1091 of the pressure-resistant top cover 109 located at the top and bottom interior surfaces of the pressure-resistant enclosure 1. The electric propulsion structure 803 includes two parallel linear actuator assemblies 8031, an actuator housing 8032, and propeller locking lugs 604 arranged in a figure-eight configuration within the actuator housing 8032. A locking pin 603 passes through the cabinet locking lug 602 located at the bottom of the server cabinet 5 and the propeller locking lug 604 to achieve coupling.

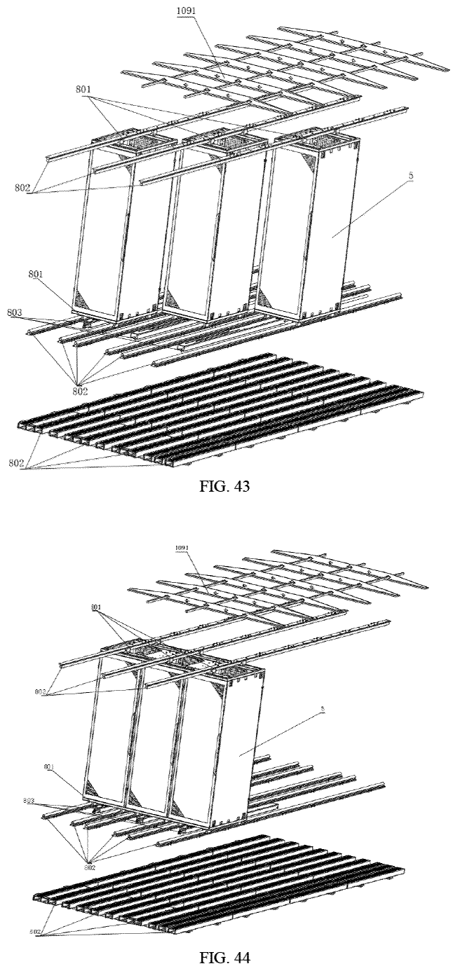

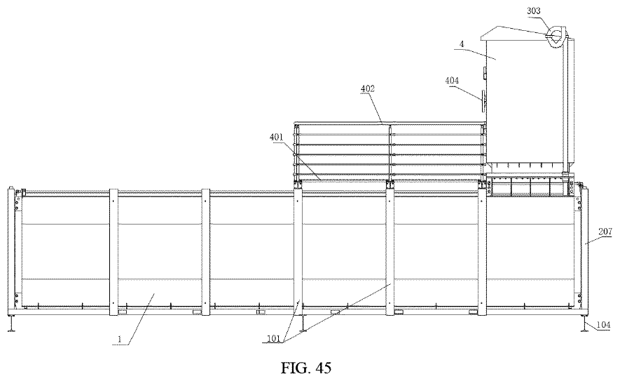

As shown in FIGS. 43-44, the server cabinet 5 slidable along the stationary and mobile mechanism may be monolithic or multi-unit. The multi-unit server cabinet may be a three-unit server cabinet. A monolithic server cabinet refers to a single unit movable along the servo guide rail 801, while a multi-unit server cabinet refers to two or more cabinets interconnected via a frame to slide as an integral unit.

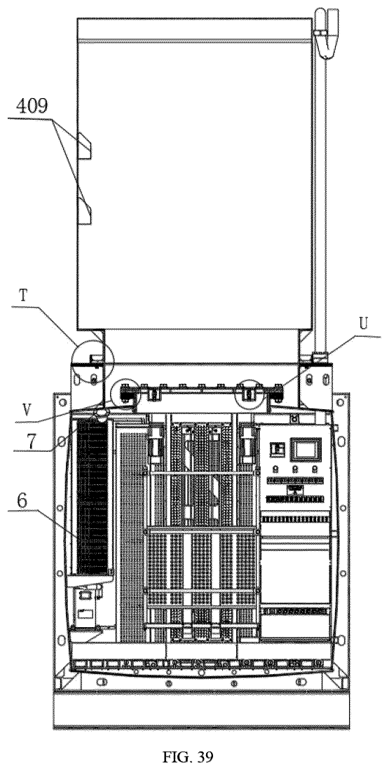

As shown in FIGS. 39-42, the pressure-resistant cabin access further includes an internal flange 1095 disposed on the pressure-resistant top cover 109 of the pressure-resistant enclosure 1, the second sealing gasket 1094, and the inner manhole sealing flange 1093. These components are fastened and sealed via inner flange bolt 1096.

As illustrated in FIG. 41, a nitrogen injection and exhaust valve manifold 906 is installed in a recessed groove on the inner manhole sealing flange 1093. The nitrogen injection and exhaust valve manifold 906 includes a shut-off valve 9061 in communication with the pressure-resistant cabin, an exhaust valve 9062 disposed above the shut-off valve 9061, and a valve chamber sealing cover 9063.

As shown in FIG. 31 and FIG. 6, the lifting guide post 207 includes the outer guide frame bushing 2075, drainage pipe 2071 disposed inside the outer guide frame bushing 2075, and hollow guide shaft 2074 arranged within the drainage pipe 2071 with a clearance fit. The drainage pipe 2071 includes drainage apertures 2076 penetrating through both ends of its pipe wall. The top end of the outer guide frame bushing 2075 is provided with an extension aperture 2072, making the length of the bushing greater than that of the hollow guide shaft 2074. A primary guide shaft positioning ring 2073 is disposed within the extension aperture 2072 to serve as a limiting structure.

The internal lighting strip 601 is mounted on the mounting rib 1091 at the inner top of the pressure-resistant cabin. The camera 7 and the temperature-humidity-oxygen-hydrogen sensor controller 602 are also mounted on the mounting ribs 1091 at the top of the interior.

A compensating air conditioner 6 is mounted to the interior side wall of the pressure-resistant cabin.

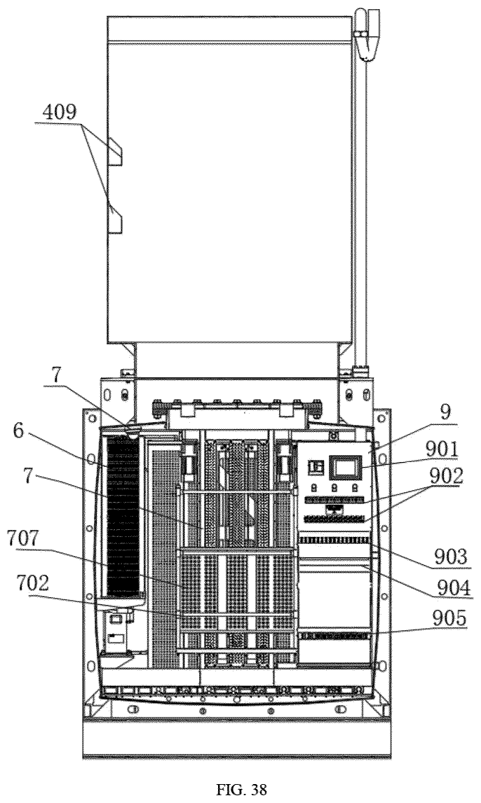

As shown in FIGS. 38-39, a storage box 409 is mounted inside the openable manhole chamber 4, which may be used to hold maintenance forms and other articles.

### Embodiment 4

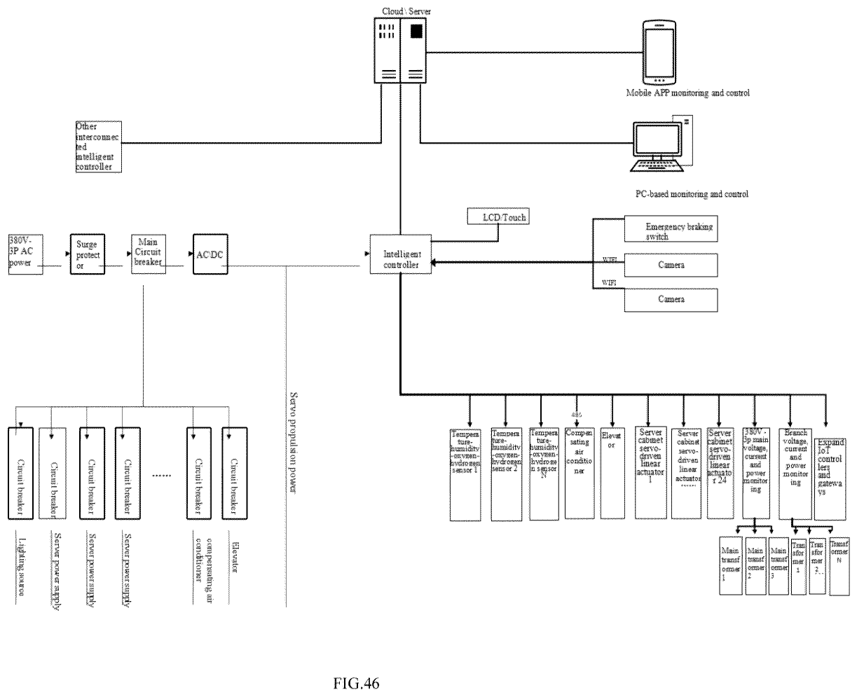

As illustrated in FIG. 46, the present embodiment differs from the Embodiment 3 in that five lateral reinforcing ribs 101 are provided on each elongated lateral surface of the side housing. A hinged manhole chamber 4 is mounted at the end portion between the first lateral reinforcing rib 101 and the outermost lateral reinforcing rib via anti-slip plate mounting bracket 405. Safety guardrails 402 are installed between the first to third lateral reinforcing ribs 101 through the anti-slip plate mounting bracket 405, thereby forming a data center structure as shown in FIG. 46. The pressure-resistant cabin access is identical to that described in Embodiment 2;
In the system of the present technical solution, referring to FIGS. 38-39 and FIG. 46, the servers 503 housed within the server cabinets 5 located inside the pressure-resistant enclosure are used for cloud data services. These servers may be monitored and controlled via a mobile application, PC terminal, or other interconnected intelligent control terminals. Each server cabinet 5 is managed by an intelligent control cabinet 9 disposed within the pressure-resistant enclosure. At least one camera 7 is provided and wirelessly connected to the intelligent control cabinet 9 via Wi-Fi. The intelligent control cabinet 9 is equipped with an intelligent control display system 901, a plurality of smart circuit breakers 902, an optical fiber splitter 903, a core optical switch 904, a power distribution unit PDU 905, and an emergency stop switch. The intelligent controller is communicatively connected with at least one temperature-humidity-oxygen-hydrogen sensor controller 602, a compensating air conditioner 6, an elevator 7, a servo drive power supply, an AC/DC module, and the linear actuator assembly 8031. In addition, it is connected to a main 3-phase voltage-current-power monitoring unit composed of multiple main current transformers, a branch voltage-current-power monitoring unit composed of multiple sub-current transformers, as well as to an expandable Internet-of-Things IoT controller and gateway. The AC/DC module is connected to a main circuit breaker and powered by a 380V 3-phase AC power supply, and it is provided with a surge protector. The main circuit breaker is connected to various branch circuit breakers supplying power to the elevator 7, the compensating air conditioner 6, server power, lighting power, and other systems.

The preferred embodiments of the present invention disclosed herein above are merely used to facilitate the explanation of the present invention. These embodiments neither exhaustively describe all details nor confine the scope of the invention solely to the specific embodiments described. Clearly, many variations and modifications may be made without departing from the spirit and scope of the present invention. The specific embodiments have been selected and described to best illustrate the principles of the present invention and its practical application, thereby enabling others skilled in the art to understand and make use of the present invention. The present invention is defined solely by the claims and their full scope and equivalents.

What is claimed is:

1. A pressure-resistant cabin is characterized by comprising a pressure-resistant cabin, an outer framework, a lifting mechanism, a pipeline system, internally disposed server cabinets, a maintenance elevator mechanism, a stationary and mobile mechanism, and an internal state monitoring system;
The pressure-resistant cabin is formed as a sealed structure by the pressure-resistant enclosure, featuring at least one access on its surface;
The outer framework includes a bottom support frame fixedly connected to the pressure-resistant enclosure, enclosure side reinforcing rib, and the lifting mechanism mounting bracket;
The lifting mechanism includes hydraulic jack and lifting guide post installed via the lifting mechanism mounting bracket;
The pipeline system includes the hydraulic pipeline and main power signal conduit sealedly extending from within the pressure-resistant enclosure, and wiring troughs positioned at the bottom inside the pressure-resistant enclosure beneath the server cabinets;
The maintenance elevator mechanism, located directly below the pressure-resistant cabin access, includes an elevator connected to a foldable floor that moves vertically;
The server cabinets are arranged in an array within the pressure-resistant enclosure, secured and maneuvered by the stationary and mobile mechanism at both upper and lower ends. Servers are arrayed within the cabinets via bracket mounting plates and server bracket mounting screws;
The stationary and mobile mechanism includes servo rails positioned between the top and bottom inside the pressure-resistant enclosure, servo rail sliders that allow the server cabinets to slide laterally along the servo rails, and an electric propulsion system;
The internal state monitoring system includes cameras and temperature-humidity-oxygen-hydrogen sensor controllers within the pressure-resistant enclosure.

2. The underwater data center according to claim 1 is characterized in that the pressure-resistant cabin access includes outer flanges fixed and sealed via outer flange nuts, the first sealing gaskets, and the external waterproof flange cover.

3. The underwater data center according to claim 1 is characterized in that the pressure-resistant cabin access includes the inner flange on the top of the pressure-resistant enclosure, the second sealing gasket, and the inner manhole sealing flange, all fixed and sealed with internal flange bolts.

4. The underwater data center according to claim 1 is characterized in that the inner manhole closure flange is provided with a nitrogen-injection and exhaust valve cluster mounted in an internal recess; The said valve cluster includes a shut-off valve communicating with the pressure-resistant cabin, an exhaust valve positioned above the shut-off valve, and a valve chamber sealing cover; The entire data center interior is nitrogen-purged during operational states.

5. The underwater data center according to claim 2 is characterized in that a manually openable manhole chamber is installed above the external waterproof flange cover, with safety guardrails and maintenance anti-slip plates positioned at the front of its entrance; The manhole chamber is equipped with a waterproof manhole door operated by a gate handwheel.

6. The underwater data center according to claim 1 is characterized in that a first support rib is disposed between the outer flange bottom of pressure-resistant cabin and the pressure-resistant enclosure, featuring conduit holes on its side for routing hydraulic pipelines.

7. The underwater data center according to claim 1 is characterized in that one end of the hydraulic pipeline is connected to the hydraulic jack via hydraulic jack joint, while the other end is connected to a hydraulic distribution valve.

8. The underwater data center according to claim 1 is characterized in that the pressure-resistant enclosure is formed by hermetically welding a single or multiple sealed pressure-resistant plates, with pressure-resistant side ribs on both sides.

9. The underwater data center according to claim 1 is characterized in that the bottom support frame includes forklift holes and an internal second support rib fixedly connected to the pressure-resistant enclosure;
Positioning holes for pipeline routing are available in the side reinforcing ribs, and an anti-slip plate mounting bracket is mounted at the top of the side ribs via mounting bolts. The anti-slip plate mounting bracket is fixedly connected to the maintenance anti-slip plate via anti-slip plate bolts.

10. The underwater data center according to claim 1 is characterized in that the lifting mechanism mounting bracket includes the X-shaped support used to connect two sets of lifting guide posts and first welding plate lugs on the sides of the hydraulic jack via positioning bolts, and the second welding plate lug connected to lifting frame mounting lugs at both ends of the pressure-resistant enclosure via lifting frame mounting bolts.

11. The underwater data center according to claim 1 is characterized in that a mounting base is respectively welded to the jacking head end of the hydraulic jack and to the bottom of the hollow shaft of the guide frame within the lifting guide post. The mounting base is fixedly secured to an I-beam base via guide frame bolts.

12. The underwater data center according to claim 1 is characterized in that the lifting guide post includes a guide frame outer sleeve, a drainage pipe disposed within the outer sleeve, and a hollow shaft disposed with a clearance fit inside the drainage pipe. Both ends of the drainage pipe wall are formed with through-type drainage holes. An extension aperture is formed at the top of the outer sleeve such that the sleeve is longer than the hollow shaft, and a main guide frame shaft positioning ring is disposed within the extension aperture for limiting displacement.

13. The underwater data center according to claim 1 is characterized in that the main power signal conduit is connected to a primary conduit extending upward from the pressure-resistant enclosure, and its top is fastened to the upper end of the openable manhole chamber via S-adapter nut. The uppermost portion of the conduit is formed in an upward-facing S-bend configuration, beneath which a waterproof drainage hole is provided.

14. The underwater data center according to claim 1 is characterized in that the servo rails and the electric propulsion structure are laterally installed on the mounting ribs disposed at both the inner top of the pressure-resistant outer shell and the inner bottom of the pressure-resistant inner shell; the electric propulsion structure includes two parallel linear actuator assemblies, an actuator housing, and propeller locking lugs arranged in a figure-eight pattern within the actuator housing, wherein interconnection is achieved by a propeller locking pin penetrating both cabinet locking lugs at the server rack base and said propeller locking lugs.

15. The underwater data center according to claim 14 is characterized in that an internal LED light strip is installed on the mounting rib at the top interior of the pressure-resistant enclosure.

16. The underwater data center according to claim 1 is characterized in that the cameras and temperature-humidity-oxygen-hydrogen sensor controllers are installed on the mounting rib located at the inner top of the pressure-resistant enclosure.

17. The underwater data center according to claim 1 is characterized in that a compensating air conditioner is installed on the inner sidewall of the pressure-resistant cabin.

18. The underwater data center according to claim 1 is characterized in that an intelligent control cabinet is further provided inside the pressure-resistant cabin. The intelligent control cabinet is equipped with a smart control display system, multiple intelligent circuit breakers, an optical fiber splitter, an optical core switch, and a power distribution unit PDU.

19. The underwater data center according to claim 1 is characterized in that a lift rack is mountable on the floor.

20. The underwater data center according to claim 5 is characterized in that a storage box is installed within the openable manhole chamber.

21. The underwater data center according to claim 1 is characterized in that the both sides of the pressure-resistant enclosure may be formed in polyhedral shapes, including tetrahedral, dodecahedral, or hexadecagonal configurations.

22. The underwater data center according to claim 1 is characterized in that the server cabinets movable via the stationary and mobile mechanism may include monolithic server cabinets or modular multi-unit server cabinets, with the latter including configurations such as three-unit server cabinets.
